(19) United States
(12) Patent Application Publication
(10) Pub. No.: US 2020/0194691 A1
(43) Pub. Date: Jun. 18, 2020

(54) EMISSIVE HOSTS DOPED WITH NON-EMISSIVE TRIPLET MATERIALS FOR ORGANIC ELECTROLUMINESCENT DEVICES

(71) Applicant: Zheng-Hong LU, Toronto (CA)

(72) Inventors: Carmen NGUYEN, Toronto (CA); Zheng-Hong LU, Toronto (CA)

(21) Appl. No.: 16/697,958

(22) Filed: Nov. 27, 2019

Related U.S. Application Data
(60) Provisional application No. 62/779,069, filed on Dec. 13, 2018.

(51) Int. Cl. H01L 51/00

(52) U.S. Cl. CPC H01L 51/0085; H01L 51/0067; H01L 51/5016; H01L 51/0074; H01L 51/0059; H01L 51/0072

(57) ABSTRACT

An emissive zone for electroluminescent devices is provided, comprising of an emissive host with small singlet-triplet energy splitting and a triplet assistant dopant with HOMO and/or LUMO energy levels within the bandgap of the host material and triplet energy greater than that of the host. The purpose of the non-emissive dopant is two-fold; charge trapping and energy transfer to the host. With careful material selection, exciton formation on the dopant and subsequent energy transfer to the host allows for excitons to be funneled to the singlet-state of the host. Reduction of long-lived excitons consequently reduces undesirable excited state annihilation processes that lead to organic degradation.

### FIELD

The present disclosure relates to the field of producing an efficient light emission zone for organic electroluminescent devices. In the emission zone there is a host material with substantially low energy separation between singlet and triplet states and a dopant material with triplet energy higher than that of the host material. The ionization energy of the dopant material's HOMO is lower than that of the host material. The dopant material functions to trap holes and form excitons. The host material receives excitonic energy transfer from the dopant and emits light.

### BACKGROUND

Since Tang and VanSlyke first demonstrated electroluminescence from organic thin films in 1987, there has been significant interest in further developing the field for application in display technology and general illumination. The first reported organic light-emitting diode (OLED) had a simple device structure consisting of two neat organic layers sandwiched between an anode and a cathode. Over the years this device structure has evolved in order to meet the high efficiency demands for practical applications. Additional layers are often added to aid in charge carrier injection and transport. Current modern emission zones in OLED devices generally consist of an organic electroluminescent material doped at low concentration into another organic material, known as the host which has a wider bandgap and higher exciton energy. Excitons are primarily formed on the host material and subsequently energy transferred to the organic dopant where radiative exciton decay can occur.

Energy transfer mechanisms are processes in which the exciton can be transferred from one molecule, called the donor, to another, known as the acceptor. There are two types of energy transfer processes. Förster energy transfer occurs through non-radiative dipole-dipole coupling while the Dexter process is through the direct electron exchange between the two interacting molecules. In the Dexter mechanism, the spin must be conserved (i.e. triplet exciton on the donor remains in the triplet-state on the acceptor).

There are two pathways for radiative decay; they are fluorescence from the singlet exciton state, or phosphorescence from the triplet exciton state. Fluorescent emitters were first used in OLEDs but its efficiencies were limited as triplet excitons could not be harvested for light emission. The introduction of phosphorescent emitters based on organometallic complexes in OLEDs enabled all generated excitons to be potentially harvested through intersystem crossing of singlets into the triplet state. Recently, a new type of emission mechanism, called thermally activated delayed fluorescence, has been found to be efficient in purely organic materials. This subset of fluorescent emitters is designed to have a small energy-splitting between the singlet and triplet excited states, thus allowing all excitons to be harvested through the reverse intersystem crossing of triplets to the singlet state. While most traditional fluorescent and phosphorescent emitters requires a host-guest emission zone in order to achieve a high efficiency, there are reports of TADFs used as hosts and of TADF molecules that can maintain a high efficiency as a neat layer (Q. Zhang, D. Tsang, H. Kuwabara, Y. Hatae, B. Li, T. Takahashi, S. Y. Lee, T. Yasuda, and C. Adachi, “Nearly 100% internal quantum efficiency in undoped electroluminescent devices employing pure organic emitters,” Adv. Mater., vol. 27, no. 12, pp. 2096-2100, 2015; D. Zhang, L. Duan, C. Li, Y. Li, H. Li, D. Zhang, and Y. Qiu, “High-efficiency fluorescent organic light-emitting devices using sensitizing hosts with a small singlet-triplet exchange energy,” Adv. Mater., vol. 26, pp. 5050-5055, 2014; C. Li, L. Duan, D. Zhang, and Y. Qiu, “Thermally Activated Delayed Fluorescence Sensitized Phosphorescence: A Strategy to Break the Trade-Off between Efficiency and Efficiency Roll-Off,” ACS Appl. Mater. Interfaces, vol. 7, no. 28, pp. 15154-15159, 2015). This provides the advantage of simplifying the emission zone.

### SUMMARY

The present disclosure provides an emissive layer, comprising:

a) at least one host material emitting in the visible-light range, with high PLQY when used as a neat homogeneous layer, the host material having a bandgap and a singlet energy state and a triplet energy state and having a singlet-triplet energy splitting in a range from about to 0 eV to about 0.4 eV to provide efficient transfer from the triplet state to the singlet state to give efficient delayed fluorescence; and

b) triplet dopant molecules dispersed throughout the host material, the triplet dopant molecules having HOMO/LUMO energy levels within the bandgap of the host material and a triplet energy level slightly greater than the triplet energy level of the host, the triplet dopant molecules having a concentration in a range from about 1 wt % to about 50 wt % of the total weight of the emissive layer.

The at least one host material may be a mixture of two different host materials forming a co-host structure which exhibits exciplex emission within the visible light range, and wherein the triplet dopant molecules have HOMO/LUMO levels selected to cause charge trapping in the co-host structure and triplet energy greater than that of the co-host exciplex emission.

The triplet dopant molecules may be selected to emit in the blue portion of the spectrum.

Other lower energy emissive triplet dopant molecules may be incorporated to achieve a broadband emission spectrum.

An multilayered emission zone may be produced using one or more of the aforementioned emissive layers, and may be further comprise other host-guest emissive layers in which emission occurs from the triplet dopant molecule, which are included in the emission zone in order to achieve a broadband emission spectrum.

The present disclosure provides an optical emission device incorporating and utilizing the aforementioned emission layer.

The optical emission device may be an organic light emitting diode (OLED).

The emission layer may be utilized in one or more EL units of a stacked OLED.

The triplet dopant molecules may be an iridium-based organometallic phosphorescent material such as, but not limited to, one of the following: tris(5-(4-fluorophenyl)-1,3-dimethyl-1H-1,2,4-triazolyl)iridium (Ir(fdpt)₃), Bis(3,5-difluoro-2-(2-pyridyl)phenyl-(2-carboxypyridyl)iridium(III) (FIrpic), fac-Iridium(III) tris(1-phenyl-3-methylbenzimidazolin-2-ylidene-C,C2′) fac-(Ir(Pmb)₃), fac-Tris[(2,6-diisopropylphenyl)-2-phenyl-1H-imidazo[e]]iridium(III) (fac-(Ir(iprpmi)₃), mer-Tris(1-phenyl-3-methylimidazolin-2-ylidene-C,C(2)′iridium(III) (mer-Ir(pmi)₃), fac-Tris(1,3-diphenyl-benzimidazolin-2-ylidene-C,C2′)iridium(III) (fac-Ir(dpbic)₃), Bis(3,5-difluoro-4-cyano-2-(2-pyridyl)phenyl-(2-carboxypyridyl) iridium(III) (FCNIrPic), Tris(2-(4,6-difuorophenyl)pyridine)iridium(III) (Ir(Fppy)₃), and Bis(3,4,5-trifluoro-2-(2-pyridyl)phenyl-(2-carboxypyridyl)iridium(III) (Ir(tfpd)₂pic).

The host material may be any one or combination of 10,10′-(4,4′-sulfonylbis(4,1-phenylene))bis(9,9-dimethyl-9,10-dihydroacridine) (DMAC-DPS), 3,6-2(Triphenylamine)-9-H-thioxanthen-9-one (3,6-2TPA-TX), 2,4-diphenyl-6-bis(12-phenylindolo)[2,3-a] carbazol-11-yl)-1,3,5-triazine (DIC-TRZ), 2-biphenyl-4,6-bis(12-phenylindolo[2,3-a]carbazole-11-yl)-1,3,5-triazine (PIC-TRZ), Triphenyltriazine spiro-biacridine (TZ-SBA), triphenylpyrimidine spiro-biacridine (PM-SBA), phenylisophthalonitrile spiro-biacridine (IPN-SBA), 2,7-Bis(9,9-dimethylacridin-10(9H)-yl)-9,9-dimethyl-9H-thioxanthene 10,10-dioxide (DMTDAC), 10-Phenyl-10H,10′H-spiro[acridine-9,9′-anthracen]-10′-one (ACRSA), and 10-(4-(4,6-diphenyl-1,3,5-triazin-2-yl)phenyl)-9,9-dimethyl-9,10-dihydroacridine (DMAC-TRZ).

A further understanding of the functional and advantageous aspects of the present disclosure can be realized by reference to the following detailed description and drawings.

### BRIEF DESCRIPTION OF THE DRAWINGS

Embodiments will now be described, by way of example only, with reference to the accompanying drawings, in which:

FIG. 1 shows the device structure of an exemplary organic light emitting diode

FIG. 2 shows the HOMO and LUMO energy levels of an exemplary organic light emitting diode with an emission zone satisfying the criteria of the invention outlined herein. Specifically, this device structure includes an assistant dopant causing hole trapping in the emission layer.

FIG. 3 illustrates the potential pathways for excitons in an emission layer using a triplet dopant to distribute excitons to the emitting host material.

FIG. 4A shows the current density-voltage-luminescence (JVL) characteristic of the exemplary OLED device for different Ir(fdpt)₃ dopant concentration.

FIG. 4B shows EL emission spectra for exemplary OLED devices at different Ir(fdpt)₃ dopant concentrations.

FIG. 5A shows the current efficiency vs. luminescence characteristics of the exemplary OLED devices at different Ir(fdpt)₃ dopant concentrations.

FIG. 5B shows the normalized luminescence over time characteristics of the exemplary OLED devices at different Ir(fdpt)₃ dopant concentrations.

FIG. 5C shows the change in voltage over time for constant applied current density (at initial luminescence of 1,000 cd/m²) of the exemplary OLED devices at different Ir(fdpt)₃ dopant concentrations.

FIG. 6 shows the current density-voltage characteristics of hole only (closed) and electron only (open) devices at different Ir(fdpt)₃ dopant concentrations.

FIG. 7 shows the HOMO and LUMO energy levels of an exemplary organic light emitting diode with an emission zone satisfying the criteria of the invention outlined herein. Specifically, this device structure includes an assistant dopant causing hole and electron trapping in the emission layer with a host comprising of a mixture of two organic materials.

### DETAILED DESCRIPTION

Various embodiments and aspects of the disclosure will be described with reference to details discussed below. The following description and drawings are illustrative of the disclosure and are not to be construed as limiting the disclosure. The figures are not to scale. Numerous specific details are described to provide a thorough understanding of various embodiments of the present disclosure. However, in certain instances, well-known or conventional details are not described in order to provide a concise discussion of embodiments of the present disclosure.

As used herein, the terms, “comprises” and “comprising” are to be construed as being inclusive and open ended, and not exclusive. Specifically, when used in the specification and claims, the terms “comprises” and “comprising” and variations thereof mean the specified features, steps or components are included. These terms are not to be interpreted to exclude the presence of other features, steps or components.

As used herein, the term “exemplary” means “serving as an example, instance, or illustration,” and should not be construed as preferred or advantageous over other configurations disclosed herein.

As used herein, the terms “about” and “approximately” are meant to cover variations that may exist in the upper and lower limits of the ranges of values, such as variations in properties, parameters, and dimensions. In one non-limiting example, the terms “about” and “approximately” mean plus or minus 10 percent or less.

As used herein, the terms “generally” and “essentially” are meant to refer to the general overall physical and geometric appearance of a feature and should not be construed as preferred or advantageous over other configurations disclosed herein.

As used herein the phrase “high PLQY” means the photoluminescence quantum efficiency of the emitting material. The PLQY is considered “high” if light emission can be observed from the material when used in a device.

As used herein the phrase “neat homogeneous layer” means the material is not doped into another material but it is the only component of the layer.

The present US utility patent application is based on U.S. provisional patent application Ser. No. 62/779,069, filed Dec. 13, 2018, which is incorporated herein by reference in its entirety.

An embodiment disclosed in the present disclosure advantageously improves the device lifetime of blue OLED devices while maintain a high efficiency. The host-guest system generally employed in current OLEDs is necessary as most emitters have reduced photoluminescence quantum efficiency (PLQY) as neat homogeneous films. This is due to quenching mechanisms that arise when excitons are in close proximity. Additionally, host materials are necessary to provide proper charge carrier transport properties leading to efficient exciton formation.

The problem presented by this structure is that the host material must have high exciton energy than the dopant in order to facilitate efficient energy transfer. For blue emitters, this requires host materials with energy levels generally in the UV-range. More highly energetic exciton species is associated with reduce device lifetime due to the degradation of the organic materials (S. Scholz, D. Kondakov, and K. Leo, “Degradation Mechanisms and Reactions in Organic Light-Emitting Devices,” 2015). This is a major cause of short device lifetimes observed, especially in blue OLED devices.

The degradation of the organic molecules is due to the formation of high energy excited states resulting from bimolecular annihilation mechanisms, which become prominent at high exciton density. The highly energetic excited states can dissipate their energy through bond dissociation of the organic materials resulting in non-radiative trap defects that reduce the luminance of the device over time. The degradation process is described in US Patent Application Publication No. 2017/0149008, in which a second dopant is incorporated into the emissive layer (EML) to act as an energy sink preventing excitonic energy from being used to dissociate the emissive dopant.

In this disclosure, the host material is a blue organic emitter while an assistant dopant is added for two purposes; charge trapping and energy transfer to the emissive host. The use of a blue emitter that can maintain its high PLQY as a neat layer eliminates the need to introduce a higher energy host material. Charge trapping by the assistant dopant helps balance the electron and hole mobility allowing more efficient exciton formation. Additionally, as excitons are primarily formed on the assistant dopant, energy transfer to the host material must occur. This energy transfer allows for the initial distribution of singlet and triplets on the host material to be altered. Through careful material selection, more excitons can be passed to the singlet state of the emissive host, thus increasing the fraction of excitons having short lifetime and undergoing prompt fluorescence.

The present invention proposes an active emission zone for electroluminescent devices consisting of an emitting host material and an assistant dopant that is not involved in light emission. Th requirements for the emission zone are:
a) Host material emitting in the visible-light range, with high PLQY when used as a neat homogeneous layer. The material should also possess a small enough singlet-triplet energy splitting to allow efficient delayed fluorescence to occur. Although, in principle, any color emitter could be used, blue emitting hosts will be the focus here, which generally have a bandgap greater than 2.5 eV to about 3.5 eV.
b) Organometallic phosphorescent dopant with highest occupied molecular orbital (HOMO) and/or lowest occupied molecular orbital (LUMO) levels within the bandgap of the host and a triplet energy level slightly greater than the host. The dopant concentration should be less than 50 wt % of the total weight of the emissive layer.

In the preferred embodiment, the invention is used in an organic light-emitting diode comprising several organic layers between an anode and a cathode. The organic layers can consist of a hole transport layer, an electron transport layer and one or more emission layers with composition as described above. Furthermore, lower energy molecular dopants (i.e. emitting in the green and red range) can also be incorporated into the proposed emissive layer or other color emission layers can be added to produce a white-emitting OLED. The former is called a single-emitting layer white OLED while the latter is an OLED utilizing a multilayered emission zone scheme. Additionally, charge carrier injection and blocking layers can also be incorporated.

The preceding general description will now be described in detail with reference to the figures. The embodiments provided are only exemplary and are not limiting.

In common OLED device structures, charge carriers are injected from the electrodes and travel through their respective charge transport layers. Ideally, electrons and holes met in the emissive zone and form an exciton on the high energy host material. From there, excitons can be energy transferred to one or more of the dopants where photon emission occurs. Alternatively, bimolecular annihilation processes between excitons or excitons and polarons can occur. They lead to higher energy exciton states which have enough energy to cause bond dissociation in the organic materials. Higher energy host materials needed for blue emitters makes it more likely for material degradation to occur. These annihilation processes are more likely to occur when there's a high density of excitons.

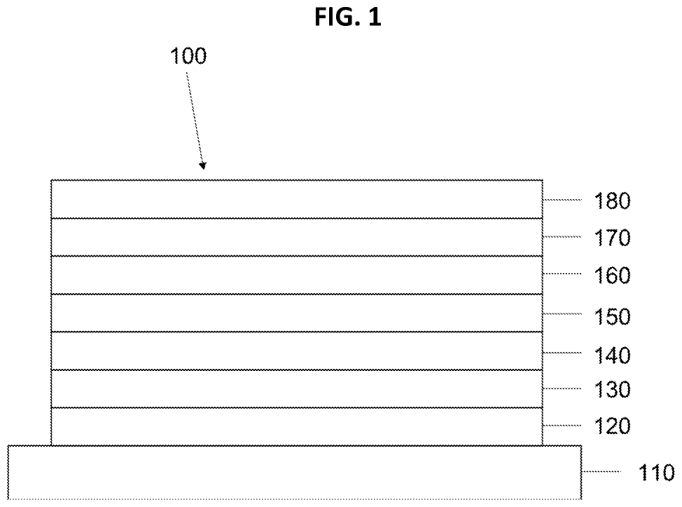

FIG. 1 illustrates one preferred embodiment of this invention. The figures are not drawn to scale. The basic OLED structure 100 comprises an anode 120 and a cathode 180 separated by three organic segments, which are a hole transport layer 140, an emission zone 150 and an electron transport layer 160. Hole injection (HIL) 130 and electron injection (EIL) 160 layers are also included. The emission zone can comprise of one or more layers which utilize the strategy disclosed herein. The entire structure is deposited onto some appropriate substrate 110, which may be rigid or flexible. This structure and others described herein are strictly exemplary and it is understood that the proposed invention can be used in a variety of other device structures.

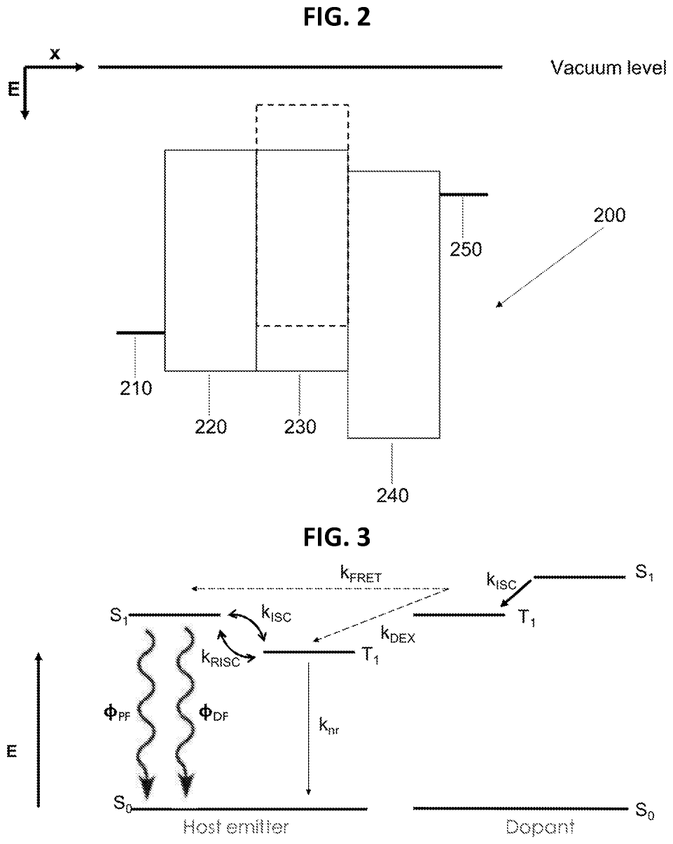

In the proposed invention, charge carrier trapping by the dopant leads to exciton formation primarily on the non-emissive assistant dopant, which then transfers the exciton to the lower energy blue host material. Since the blue emitter is also the host material, it eliminates the need for host materials in the UV energy range that are more likely to induce chemical bond dissociation. Additionally, the assistant dopant can be chosen to help shift and broaden the recombination zone throughout the emissive layer in order to reduce the local exciton density. Depending on the relative HOMO/LUMO energy level of the dopant to the host material, the dopant can cause hole or electron trapping that slows the charge carrier transport through the emissive layer. If carefully chosen, the dopant can be used to create better electron and hole balance leading to more efficient and stable devices. This concept has been demonstrated previously for hole trapping, as disclosed in US Patent Application Publication No. 2013/0126852. FIG. 2 illustrates the HOMO and LUMO energy levels of an electroluminescent device 200 that satisfies the criteria of the described invention. It shows the work function of the anode/hole injection layer 210, the energy levels for the hole transport layer 220, the emissive layer 230, the electron transport layer 240, and the work function for the cathode/electron injection layer 250. The energy levels of the dopant and host material are shown in the emissive layer 230. In this embodiment, hole mobility is greater than electron mobility through the blue host material and thus an assistant dopant that induces hole trapping is utilized. Without the dopant, excitons are primarily formed at the interface between the emissive zone and the electron transport layer. The high local density of excitons at the interface results in significant high energy exciton quenching.

The novel purpose for the dopant proposed here is to energy transfer excitons to the blue host emitter and in doing so, alter the ratio of singlet to triplet excitons initially formed on the blue emitter. The assistant dopant is an organometallic complex with high intersystem crossing rate so that all excitons are quickly transferred to the triplet state. As the electronic transition from the triplet to ground state is allowed, excitons can be transferred to the blue host emitter through either Förster or Dexter mechanism. Förster would lead to singlet excitons while Dexter results in triplets on the blue emitter. In the preferred embodiment, the blue emitter is a TADF molecule so that both singlet and triplet excitons can be harvested. The relative excitonic energy levels as well as possible exciton pathways between the host and dopant material are illustrated in FIG. 3. ϕ_{PF}, ϕ_{DF}, k_{RISC}, k_{ISC} and kₙᵣ are material constants of the host and correspond to the fraction of excitons undergoing prompt fluorescence, the fraction of excitons undergoing delayed fluorescence, the rate constant for reverse intersystem cross, intersystem crossing and non-radiative decay, respectively. k_{FRET} and k_{DEX} are the rate constants for Förster and Dexter energy transfer, respectively.

The number of excitons transferred to the singlet state of the blue emitting host material can be maximized by optimizing the Förster transfer process. To do this, host and dopant materials can be chosen to have significant overlap between the absorption spectrum of the blue host and the emission spectrum of the assistant dopant.

Normally in electroluminescence, excitons are formed in a 1:3 ratio of singlets to triplets. In TADF molecules, some portion of the initial singlet population undergoes prompt fluorescence. The remaining singlets cycle between the singlet and triplet states until eventually decaying from the singlet state through delayed fluorescence. These longer-lived excitons are more likely to undergo undesirable bimolecular annihilation processes that lead to bond dissociation in the organics. Reducing the population of long-lived excitons by funneling more excitons into the prompt fluorescence pathway results in a decline in detrimental exciton-exciton annihilation processes and consequently, extends the operational device lifetime.

The triplet dopant molecules may an iridium-based organometallic phosphorescent material such as, but not limited to, one of the following: tris(5-(4-fluorophenyl)-1,3-dimethyl-1H-1,2,4-triazolyl)iridium (Ir(fdpt)₃), Bis(3,5-difluoro-2-(2-pyridyl)phenyl-(2-carboxypyridyl)iridium(III) (FIrpic), fac-Iridium(III) tris(1-phenyl-3-methylbenzimidazolin-2-ylidene-C,C2′) fac-(Ir(Pmb)₃), fac-Tris[(2,6-diisopropylphenyl)-2-phenyl-1H-imidazo[e]]iridium(III) (fac-(Ir(iprpmi)₃), mer-Tris(1-phenyl-3-methylimidazolin-2-ylidene-C,C(2)′iridium(III) (mer-Ir(pmi)₃), fac-Tris(1,3-diphenyl-benzimidazolin-2-ylidene-C,C2′)iridium(III) (fac-Ir(dpbic)₃), Bis(3,5-difluoro-4-cyano-2-(2-pyridyl)phenyl-(2-carboxypyridyl) iridium(III) (FCNIrPic), Tris(2-(4,6-difuorophenyl)pyridine)iridium(III) (Ir(Fppy)₃), and Bis(3,4,5-trifluoro-2-(2-pyridyl)phenyl-(2-carboxypyridyl)iridium(III) (Ir(tfpd)₂pic).

The host material may be any one or combination of 10,10′-(4,4′-sulfonylbis(4,1-phenylene))bis(9,9-dimethyl-9,10-dihydroacridine) (DMAC-DPS), 3,6-2(Triphenylamine)-9-H-thioxanthen-9-one (3,6-2TPA-TX), 2,4-diphenyl-6-bis(12-phenylindolo)[2,3-a] carbazol-11-yl)-1,3,5-triazine (DIC-TRZ), 2-biphenyl-4,6-bis(12-phenylindolo[2,3-a]carbazole-11-yl)-1,3,5-triazine (PIC-TRZ), Triphenyltriazine spiro-biacridine (TZ-SBA), triphenylpyrimidine spiro-biacridine (PM-SBA), phenylisophthalonitrile spiro-biacridine (IPN-SBA), 2,7-Bis(9,9-dimethylacridin-10(9H)-yl)-9,9-dimethyl-9H-thioxanthene 10,10-dioxide (DMTDAC), 10-Phenyl-10H,10′H-spiro[acridine-9,9′-anthracen]-10′-one (ACRSA), and 10-(4-(4,6-diphenyl-1,3,5-triazin-2-yl)phenyl)-9,9-dimethyl-9,10-dihydroacridine (DMAC-TRZ), but it will be appreciated that the host material is not limited to this list, these are simply non-limiting examples.

### EXAMPLE

The following is provided as a proof of concept and is not limiting to the scope of the invention. In FIG. 2, the host and dopant in the emissive layer 230 are 10,10′-(4,4′-Sulfonylbis(4,1-phenylene))bis(9,9-dimethyl-9,10-dihydroacridine) (DMAC-DPS) and tris(5-(4-fluorophenyl)-1,3-dimethyl-1H-1,2,4-triazolyl)iridium (Ir(fdpt)₃), respectively. DMAC-DPS is a blue TADF material with photoluminescent quantum yield of 0.88 as a neat film. If(fdpt)₃ is a phosphorescent material with shallower HOMO level than DMAC-DPS and slightly greater triplet energy (T₁=2.9-3 eV). The HTL 220 and ETL 240 are DMAC-DPS and 3,3′,3″-[Borylidynetris(2,4,6-trimethyl-3,1-phenylene)]tris [pyridine] (3TPYMB), respectively. Layers 210 and 250 are the work functions of the anode/HIL and cathode/EIL which comprise of ITO/Molybdenum trioxide (MoO₃) and Aluminum/Lithium Fluoride (LiF), respectively.

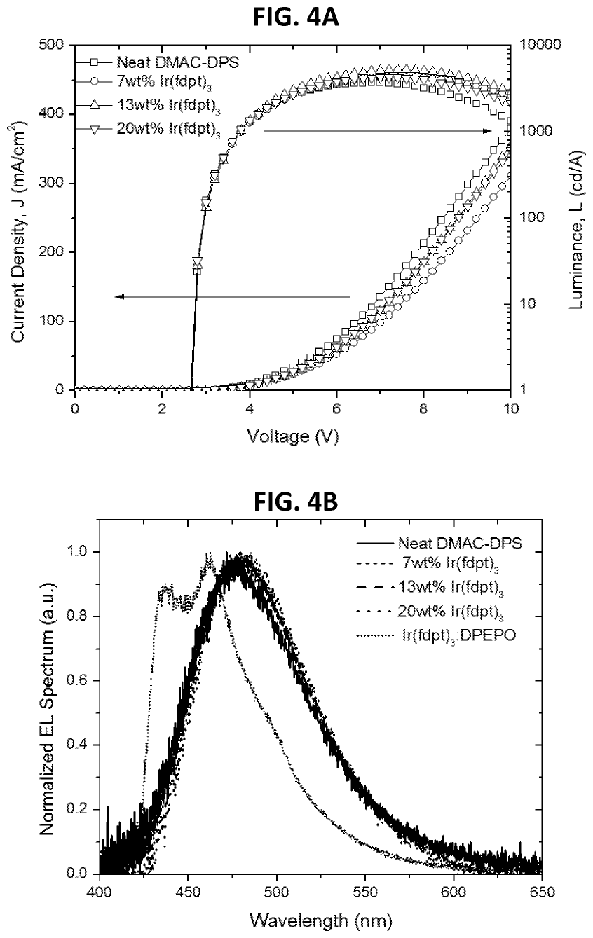

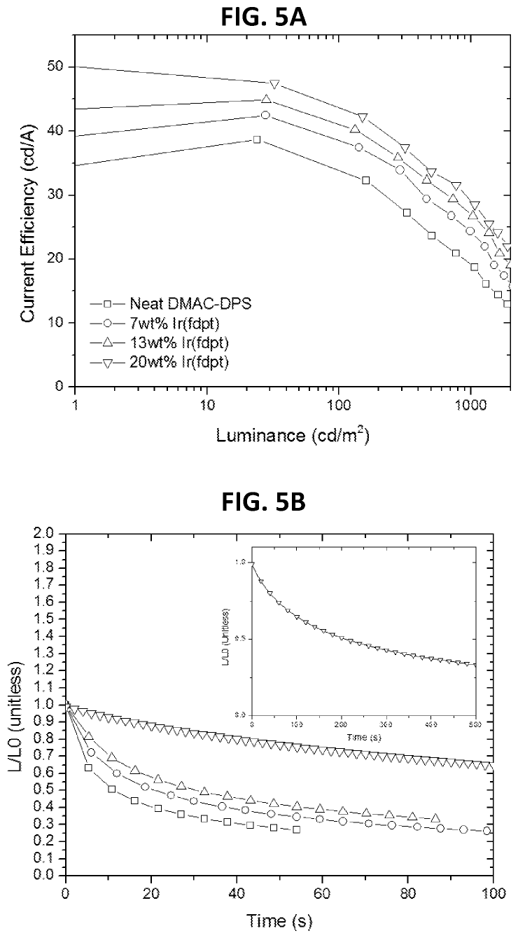

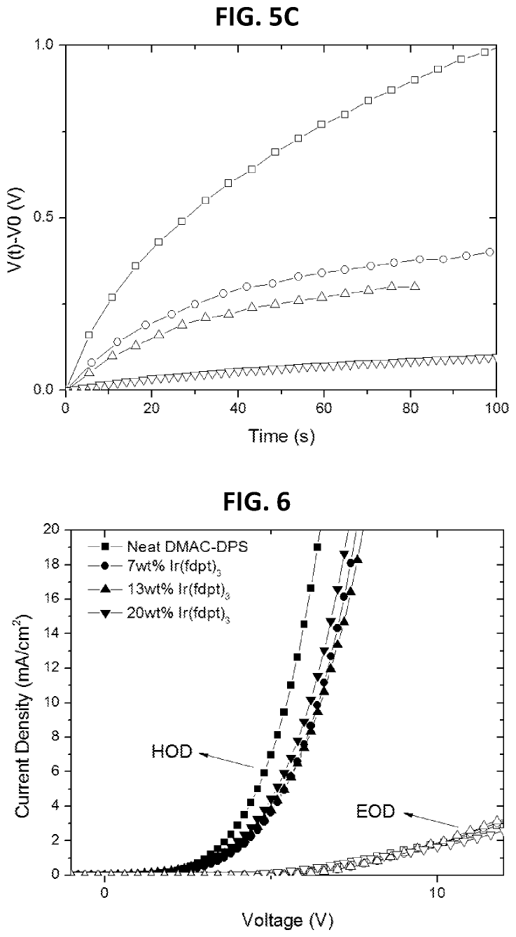

FIGS. 4A and 4B shows the current density-voltage-luminescence (JVL) and the electroluminescence emission spectrum, respectively, of neat DMAC-DPS, DMAC-DPS doped with Ir(fdpt)₃ at different concentrations and emission from only Ir(fdpt)₃. Together, they demonstrate that the dopant causes charge trapping in the emissive layer and allows efficient energy transfer to the blue emitter host, even at higher concentration of the dopant. FIGS. 5A and 5B provide the current efficiency and luminance over time (at an initial luminescence, L₀, of 1,000 cd/m²) plots, respectively, for the OLED devices with different concentrations of Ir(fdpt)₃. An improvement in both efficiency and device operational lifetime is observed at higher dopant concentrations. The device lifetime of the 20 wt. doped DMAC-DPS is ˜20 times greater than that of undoped DMAC-DPS. As more excitons are funneled into the singlet state of the DMAC-DPS, more excitons are used efficiency towards prompt fluorescence. This also reduced the fraction of long-lived excitons that are more likely to be involved in chemical bond dissociative reactions. Additionally, the degradation of the organic materials leads to non-radiative defects that can act as traps for charge carriers (Y. Zhang, J. Lee, and S. R. Forrest, “Tenfold increase in the lifetime of blue phosphorescent organic light-emitting diodes,” Nat. Commun., vol. 5, pp. 1-7, 2014). The trap defects are charged when filled and lead to an increase in voltage over time. The reduction in the change in voltage over time at higher dopant concentrations, FIG. 5C, indicates a decrease trap defects being formed from degradation mechanisms.

As mentioned previously, charge trapping can lead to a shifting/broadening of the recombination zone and better charge carrier balance that can lead to improved OLED device lifetime. Single carrier devices are shown in FIG. 6 to further study the conduction mechanism and show improved device lifetime is not solely due to charge trapping. The hole only devices (HOD) show a significant reduction in current density with the addition of the dopant while the current density is unchanged in the electron only devices (EOD). This is expected based on the relative HOMO and LUMO energy levels of the host and dopant. The reduction in the hole carrier capacity would shift the recombination zone away from the EML/ETL and towards the center of the EML. However, a continued trend of reduced hole conduction is not observed at higher dopant concentrations. If better charge balance was the only cause of improved device lifetime then there should be a trend of reduced hole current density with dopant concentration. This is not observed and thus is cannot be the sole explanation the improved lifetime observed, particularly in the 20 wt % doped device where the operational lifetime was drastically improved but the current density in the HOD is not significantly different from the other dopant concentrations.

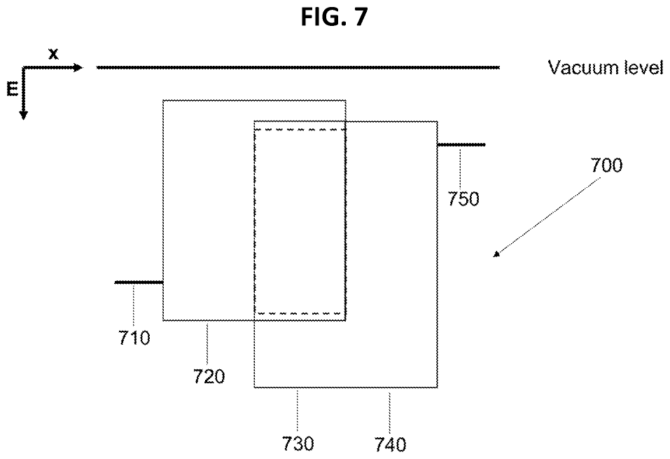

FIG. 7 illustrates energy levels of an electroluminescent device 700 that satisfies the criteria of this embodiment. It shows the work function of the anode/hole injection layer 710, the energy levels for the hole transport layer 720, the emissive layer 730, the electron transport layer 740, and the work function for the cathode/electron injection layer 750. The energy levels of the dopant and host materials are shown in the emissive layer 730. In this embodiment, the host materials are composed of a hole-transporting and an electron-transporting material. Exciplex emission would occur from the co-host structure in which the exciton resides on both materials; the hole is on the hole-transporting material and the electron on the electron-transporting material.

The foregoing description of the preferred embodiments of the invention has been presented to illustrate the principles of the invention and not to limit the invention to the particular embodiment illustrated. It is intended that the scope of the invention be defined by all of the embodiments encompassed within the following claims and their equivalents.

1. An emissive layer, comprising:
a) at least one host material emitting in the visible-light range, with high PLQY when used as a neat homogeneous layer, said host material having a bandgap and a singlet energy state and a triplet energy state and having a singlet-triplet energy splitting in a range from about to 0 eV to about 0.4 eV to provide efficient transfer from said triplet state to said singlet state to give efficient delayed fluorescence; and
b) triplet dopant molecules dispersed throughout said host material, said triplet dopant molecules having HOMO/LUMO energy levels within said bandgap of the host material and a triplet energy level slightly greater than the triplet energy level of the host, said triplet dopant molecules having a concentration in a range from about 1 wt % to about 50 wt % of the total weight of the emissive layer.

2. The emission layer according to claim 1, wherein said at least one host material is a mixture of two different host materials forming a co-host structure which exhibits exciplex emission within the visible light range, and wherein said triplet dopant molecules have HOMO/LUMO levels selected to cause charge trapping in the co-host structure and triplet energy greater than that of the co-host exciplex emission.

3. The emission layer according to claim 1, wherein said triplet dopant molecules are selected to emit in the blue portion of the spectrum.

4. The emission layer according to claim 2, wherein said triplet dopant molecules are selected to emit in the blue portion of the spectrum.

5. The emission layer according to claim 3, wherein other lower energy emissive triplet dopant molecules are incorporated to achieve a broadband emission spectrum.

6. The emission layer according to claim 4, wherein other lower energy emissive triplet dopant molecules are incorporated to achieve a broadband emission spectrum.

7. A multilayered emission zone, wherein one or more of the emissive layers is that of claim 1, and further comprising other typical host-guest emissive layers in which emission occurs from the triplet dopant molecule, which are included in the emission zone in order to achieve a broadband emission spectrum.

8. A multilayered emission zone, wherein one or more of the emissive layers is that of claim 2, and further comprising other typical host-guest emissive layers in which emission occurs from the triplet dopant molecule, which are included in the emission zone in order to achieve a broadband emission spectrum.

9. An optical emission device incorporating and utilizing the emission layer according to claim 1.

10. An optical emission device incorporating and utilizing the emission layer according to claim 2.

11. An optical emission device incorporating and utilizing the emission layer according to claim 3.

12. An optical emission device incorporating and utilizing the emission layer according to claim 4.

13. An optical emission device incorporating and utilizing the emission layer according to claim 5.

14. The optical emission device according to claim 9, wherein the device is an organic light emitting diode (OLED).

15. The optical emission device according to claim 10, wherein the device is an organic light emitting diode (OLED).

16. The optical emission device according to claim 11, wherein the device is an organic light emitting diode (OLED).

17. The optical emission device according to claim 12, wherein the device is an organic light emitting diode (OLED).

18. The optical emission device according to claim 13, wherein the device is an organic light emitting diode (OLED).

19. The device of claim 14, wherein OLED is a stacked OLED.

20. The device of claim 1, wherein said triplet dopant molecules is an iridium-based organometallic phosphorescent material such as one of the following: tris(5-(4-fluorophenyl)-1,3-dimethyl-1H-1,2,4-triazolyl)iridium (Ir(fdpt)₃), Bis(3,5-difluoro-2-(2-pyridyl)phenyl-(2-carboxypyridyl)iridium(III) (FIrpic), fac-Iridium(III) tris(1-phenyl-3-methylbenzimidazolin-2-ylidene-C,C2′) fac-(Ir(Pmb)₃), fac-Tris[(2,6-diisopropylphenyl)-2-phenyl-1H-imidazo[e]]iridium(III) (fac-(Ir(iprpmi)₃), mer-Tris(1-phenyl-3-methylimidazolin-2-ylidene-C,C(2)′iridium(III) (mer-Ir(pmi)₃), fac-Tris(1,3-diphenyl-benzimidazolin-2-ylidene-C,C2′)iridium(III) (fac-Ir(dpbic)₃), Bis(3,5-difluoro-4-cyano-2-(2-pyridyl)phenyl-(2-carboxypyridyl) iridium(III) (FCNIrPic), Tris(2-(4,6-difuorophenyl)pyridine)iridium(III) (Ir(Fppy)₃), and Bis(3,4,5-trifluoro-2-(2-pyridyl)phenyl-(2-carboxypyridyl)iridium(III) (Ir(tfpd)₂pic).

21. The device of any one of claim 1, wherein said host material is selected from the group consisting of 10,10′-(4,4′-sulfonylbis(4,1-phenylene))bis(9,9-dimethyl-9,10-dihydroacridine) (DMAC-DPS), 3,6-2(Triphenylamine)-9-H-thioxanthen-9-one (3,6-2TPA-TX), 2,4-diphenyl-6-bis(12-phenylindolo)[2,3-a] carbazol-11-yl)-1,3,5-triazine (DIC-TRZ), 2-biphenyl-4,6-bis(12-phenylindolo[2,3-a]carbazole-11-yl)-1,3,5-triazine (PIC-TRZ), Triphenyltriazine spiro-biacridine (TZ-SBA), triphenylpyrimidine spiro-biacridine (PM-SBA), phenylisophthalonitrile spiro-biacridine (IPN-SBA), 2,7-Bis(9,9-dimethylacridin-10(9H)-yl)-9,9-dimethyl-9H-thioxanthene 10,10-dioxide (DMTDAC), 10-Phenyl-10H,10′H -spiro[acridine-9,9′-anthracen]-10′-one (ACRSA), and 10-(4-(4,6-diphenyl-1,3,5-triazin-2-yl)phenyl)-9,9-dimethyl-9,10-dihydroacridine (DMAC-TRZ).
